(19) United States
(12) Patent Application Publication
(10) Pub. No.: US 2002/0079974 A1
(43) Pub. Date: Jun. 27, 2002

(54) Method for tuning a PLL circuit

(75) Inventors: Guenther Bergmann, Blaustein (DE); Frank Gruson, Heidenheim (DE)

Correspondence Address: FASSE PATENT ATTORNEYS, P.A., P.O. BOX 726, HAMPDEN, ME, 04444-0726, US

(73) Assignee: ATMEL Germany GmbH, Heilbronn (DE)

(21) Appl. No.: 09/996,521

(22) Filed: Nov. 28, 2001

(30) Foreign Application Priority Data
Dec. 22, 2000 (DE) 100 64 476.7

(51) Int. Cl. H03L 7/00

(52) U.S. Cl. 331/17

(57) ABSTRACT

In the previously known methods for tuning the PLL circuit, the loop filter has to be discharged again if the PLL circuit does not lock in. During this time, also known as dead time, the PLL circuit cannot detect any signals. With the new method, the PLL circuit can also detect signals during the discharge period of the loop filter. This avoids dead times and the signal detection by the PLL circuit is substantially accelerated. The data throughput is increased, especially when used in high-frequency applications such as, for example, in the field of mobile telephones.

### BACKGROUND

1. Field of the Invention

The present invention relates to a method for tuning a PLL circuit according to the preamble of patent claim 1.

2. Description of the Related Technology

PLL circuits are used for the phase-locked coupling between a useful frequency and a reference frequency. In general, they are fully integrated except for a few external components such as coils and capacitors. The sending and receiving units for wireless communication, in the field of mobile telephones for example, are an important area of application for PLL circuits. In general, PLL circuits consist of a phase detector, which compares the frequency or phase of an oscillator with the frequency or phase of a useful signal and supplies pulse-width modulated current pulses at the output, a loop filter, which converts the current pulses of the phase detector into a direct voltage, a voltage controlled oscillator, whose frequency is changed by the direct voltage of the loop filter. Various types of control mechanisms are used, depending upon the area of application of the PLL circuit. A particularly frequent type is that in which the oscillator increases its frequency as the voltage at the loop filter increases until the phase difference between the oscillator frequency and the useful frequency at the input of the phase detector becomes minimal. There is then a phase-locked coupling between the oscillator frequency and the useful frequency, and the PLL circuit is locked in.

In the methods known to the state of the art, for example that presented by T. Yamawaki et al, “A 2.7 V GSM RF Transceiver IC”, IEEE Journal of Solid-State-Circuits Vol. 32, No. 12, December 1997 and “Hitachi Semiconductors, Datasheet HD155121F, RF Transceiver IC for GSM and PCS”, a constant offset current source is installed which charges the loop filter up to a maximum voltage during the predetermined period of time, also known as the time slot. Provided that the PLL circuit does not lock in within this period, the loop filter is completely discharged by means of a reset switch. The disadvantage of the previous method is that the PLL circuit has a dead time during the reset phase during which signal processing cannot take place. This becomes disturbingly noticeable in the case of signal processing in the range up to several GHZ.

### SUMMARY OF THE INVENTION

The object of the present invention is to provide a method with which signal detection can be performed with a PLL circuit without dead times. A further object of the invention is to specify a circuit arrangement for implementing the method which can be easily and economically manufactured.

The first mentioned object is solved by the features of patent claim 1, the solution to the second mentioned object is shown in features of patent claim 9. Favorable embodiments are the objects of the subclaims.

Accordingly, the essence of the invention lies in changing the control voltage of an oscillator in a PLL circuit bi-directionally within a defined voltage interval during the signal detection until the PLL circuit locks in. For this, a PLL circuit, in which the output frequency of an oscillator is determined by a phase detector by means of a loop filter generated control voltage, compares the output frequency of the oscillator in the phase detector with the desired frequency, and in a first operating mode the control voltage of the oscillator, starting from a lower threshold value, increases until its output frequency matches the desired frequency, or the control voltage, upon reaching an upper threshold value in a second operating mode, decreases until the output frequency matches the desired frequency or switches back into the first operating mode upon reaching the lower threshold value.

The advantages of the new method compared with the previous state of the art are that a dead time in the PLL circuit, caused by the discharge of the loop filter, is avoided within the reset phase and the signal processing is significantly accelerated, especially at high frequencies. As the voltage of the loop filter, as a control voltage, determines the output frequency of the oscillator, it is advantageous to adjust the voltage interval between the lower and upper threshold values to the dynamic range (frequency range) of the voltage controlled oscillator, whereby the voltage range in the range of the digital signal processing spans about 3 volts, for example. Moreover, it is advantageous to store the current operating mode of the PLL circuit in order to determine the direction of the voltage change when the operating mode changes.

In a development of the method, the control voltage is changed by means of a current source or a current sink which are alternately linked to the loop filter by means of a switching element. In so doing, the currents of the current source or the current sink overlay the pulse-width modulated currents of the phase detector. In the first operating mode, the loop filter, which comprises an RC combination for example, is charged by the current source, so that the frequency of the oscillator is increased at the output of the loop filter at which the control voltage is available, and the voltage at the loop filter is increased if the PLL circuit does not lock in. The control unit compares, by means of a comparator for example, the control voltage of the oscillator with the defined upper limiting value of the control voltage and separates the current source from the loop filter when the limiting value is reached. In the second operating mode, the control unit links the loop filter to the current sink until the lower limiting value of the control voltage is reached. This procedure is continued until the PLL circuit locks in and the current source or the current sink is separated, and the control voltage of the oscillator remains constant and is determined exclusively by the current signals of the phase detector. The advantage of current sources is that the high impedance outlets make the output currents independent of the voltage amplitude of the loop filter. Moreover, it is advantageous compared to the previous state of the art if the currents of the current source and current sink are equal and opposite and temporally constant. This makes the sensitivity and the speed of locking in of the PLL circuit independent of the direction of change of the control voltage and the operating mode.

In a development of the method, the current of the current source or the current of the current sink is compensated by the current of the phase detector if the desired frequency matches the useful frequency, that is in the locked-in state. In this way, the control voltage of the oscillator remains constant without the current sink or current source having to be separated by means of the switching element. The advantage here is that no switching voltages occur at the time when the PLL circuit has a particularly high sensitivity. Moreover, faster locking-in is possible in the next search procedure, particularly if the new frequency only differs slightly from the old frequency as the last voltage value is used as the starting point.

In another development of the method, the control voltage is modulated by a temporally variable current from the phase detector provided that the output frequency of the oscillator does not match the desired frequency, while the frequency of the current falls as the difference between the output frequency and the desired frequency decreases. It is particularly advantageous here if the amplitude of the current of the phase detector is larger than the current of the current source or the current of the current sink. In another development of the method, in addition to the frequency, the amplitude of the current, which is supplied by the phase detector, is also changed by the phase detector, by means of reducing the amplitude as the difference between the output frequency and the desired frequency becomes greater.

In another development of the method, the modulation frequency of the current of the phase detector is selected so that, in the case of a large difference between the desired frequency and the oscillator frequency, the low pass characteristic of the loop filter strongly damps the modulation amplitude of the control voltage. The PLL circuit is thus insensitive when there are large frequency differences at the input of the phase detector, and the control voltage at the oscillator is still relatively quickly raised or lowered as the current of the current source or the current of the current sink is not yet compensated by the current of the phase detector.

The present, new circuit arrangement can be used in an advantageous manner for implementing the method according to the invention. It creates a tuning circuit for supplying an offset current for a PLL circuit arrangement with the following features: a control unit which compares a control voltage available at the oscillator or loop filter voltage with a lower threshold value and with an upper threshold value, and depending on the comparison, in a first operating mode links the input of a loop filter to or separates it from a current source by means of a switching element, and in a second operating mode links the loop filter to or separates it from a current sink, and stores the current operating mode in a memory unit.

The advantage of the tuning circuit in respect of the second named object of the present invention compared with the state of the art lies in the fact that the circuit arrangement enables the PLL circuit to lock in very quickly because no dead times occur. The signal processing is thus considerably accelerated and enables the use of very high frequencies in the range of several GHZ. This is an important factor for use in the field of mobile-radio.

### BRIEF DESCRIPTION OF THE FIGURES

The method according to the invention is described in the following by means of an embodiment in conjunction with the drawings. They show:

FIG. 1 an embodiment of a PLL circuit arrangement with integrated tuning unit, and

FIG. 2 the voltage curve at the loop filter against time for the case when the PLL circuit arrangement does not lock in, and

FIG. 3 the voltage curve at the loop filter against time for the case when the PLL circuit arrangement locks in.

### DESCRIPTION OF THE PREFERRED EMBODIMENTS

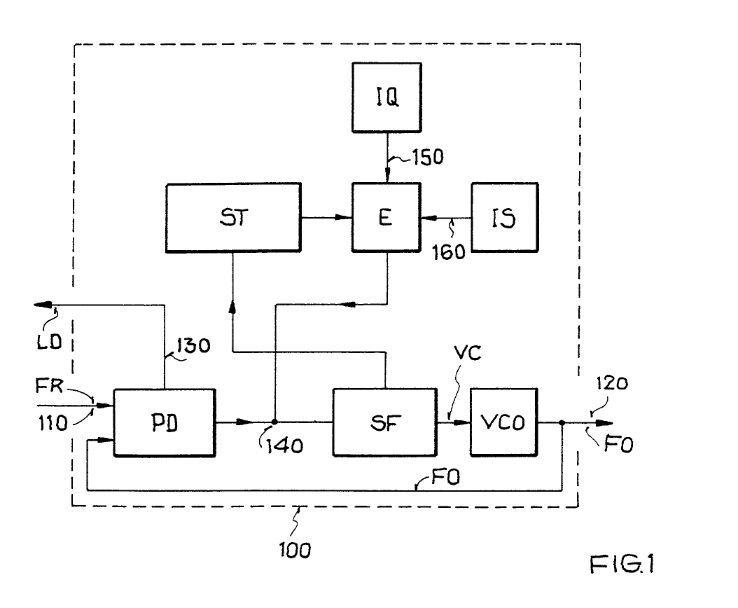

The object of the PLL circuit arrangement 100 shown in FIG. 1 is to change the frequency FO of an oscillator VCO by a bi-directional change of the control voltage VC within a defined interval until its frequency FO matches the desired frequency FR and the PLL circuit arrangement 100 locks in. For this purpose, the PLL circuit arrangement 100 has an input 110 at which the desired frequency FR from a previous switching stage (not shown) is available, a first output node 120, at which the oscillator frequency FO is available for a subsequent switching stage (not shown), and a second output 130, at which it is indicated by means of a lock-in signal LD of a subsequent switching stage (not shown) that the PLL circuit arrangement 100 has locked in.

The input 110 is linked to a first input of a phase detector PD within the PLL circuit arrangement 100. Moreover, the phase detector PD has a second input which is linked to a node 120 at which the frequency FO of the output of a voltage controlled oscillator VCO is available, a first output which is linked to the node 140 and a second output, at which the lock-in signal LD is available, which is linked to the second output 130 of the PLL circuit arrangement 100. The frequency FO of the oscillator VCO may be adjusted by, for example, a divider or mixer (neither is shown) if the difference between the frequencies available at the first and second inputs of the phase detector PD is too great. In addition, the output of a switching element E is still linked to the node 140. Moreover, the input of a control unit ST is linked to a first output of a loop filter SF. Furthermore, the output of the control unit ST is wired to a first input of the switching element E. Apart from that, in the case of switching element E, a second input 150 is linked to a current source IQ and a third input 160 is linked to a current sink IS. Moreover, the input of the loop filter SF is wired to the node 140, whereby the output of the loop filter SF, at which the control voltage VC is available, is linked to the input of the voltage controlled oscillator VCO.

The following describes the principle of operation of the PLL circuit arrangement 100, which automatically changes the control voltage VC for the voltage controlled oscillator VCO bi-directionally within a voltage interval defined by the control unit ST until the oscillator frequency FO matches the desired frequency FR, i.e. the PLL circuit has locked in. In the locked in state, the PLL circuit arrangement 100 shows, by means of the signal LD of a subsequent switching stage (not shown), that the signal FO available at the output node 120 is valid.

If the PLL circuit arrangement 100 has not locked in, the loop filter SF, which comprises an RC combination for example, is charged or discharged with the pulse-width modulated current of the phase detector PD and the current of the current source IQ or the current sink IS. In which case the modulation frequency of the current of the phase detector PD is proportional to the frequency difference between the oscillator frequency FO and the input frequency FR. The resulting voltage at the loop filter SF is available at the second output of the loop filter SF as control voltage VC and thus determines the frequency FO of the oscillator VCO. The control unit ST, which contains a comparator for example, monitors the voltage at the loop filter SF and switches into a first operating mode when the lower limiting value of the control voltage VC is reached, and into a second operating mode when the upper limiting value of the control voltage VC is reached. If the control unit ST has a memory unit in addition to the comparator, then the current operating mode of the PLL circuit arrangement 100 can be stored and used as the starting point for changing the operating mode.

In the first operating mode, the control unit ST links the current source IQ, which supplies a constant current for example, to the node 140 by means of the switching element E. The control voltage VC and the output frequency FO of the oscillator VCO thereby increase until the control unit ST, which compares the voltage value of the loop filter SF with a defined upper limiting value, separates the current source IQ from the node 140 again by means of the switching element E when the upper limiting value is reached. In the second operating mode, the control unit ST links the current sink IS, whose current corresponds to the current of the current source IQ for example, to the node 140 by means of the switching element E. The control voltage VC and the output frequency FO of the oscillator VCO thereby fall until the control unit ST, which compares the voltage value of the loop filter SF with a defined lower limiting value, separates the current sink IS from the node 140 again by means of the switching element E when the lower limiting value is reached.

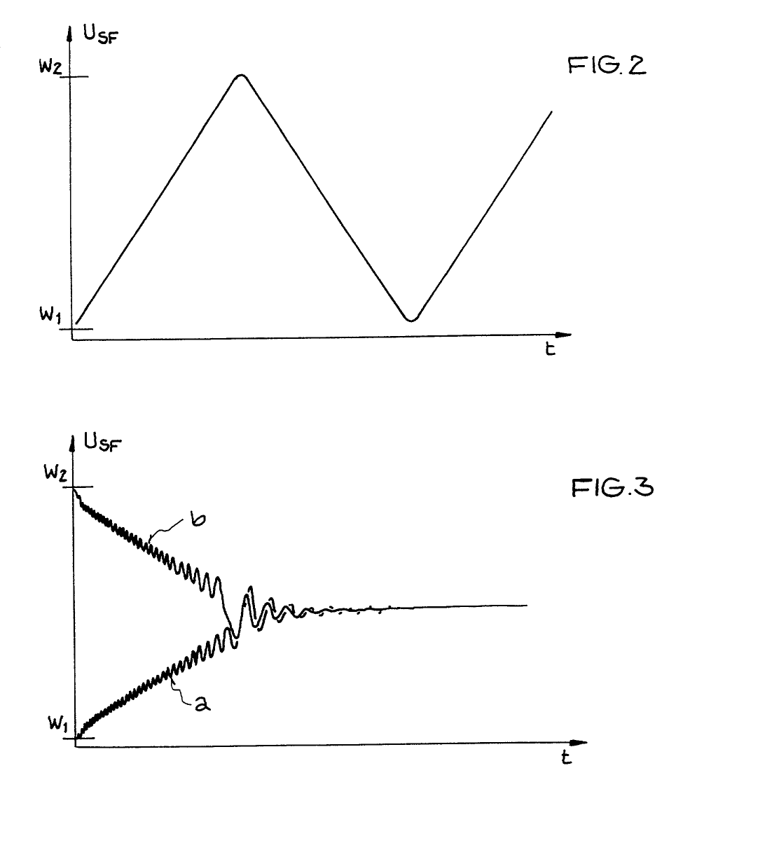

FIG. 2 shows the temporal course of the voltage at the loop filter SF for both operating states. The amplitude of the voltage at the loop filter SF or the control voltage of the oscillator VCO is plotted here on the Y axis, whereby the interval within which the control voltage is changed is defined by a lower threshold value W1 and an upper threshold value W2. Moreover the X-axis is the time axis. Starting at the lower threshold value W1, the voltage is continually increased in the first operating state by the current source IQ supplying a constant current to the loop filter SF. When the voltage at the loop filter SF reaches the upper limiting value W2, the control unit ST switches from the first into the second operating state and the voltage at the loop filter SF is continuously lowered down to the lower limiting value W1 by the constant current of the current sink IS, the amplitude of which current corresponds to that of the current source IQ. As the two currents in the example shown are equal and opposite, the slope of the ascending limb in the figure corresponds to that of the descending limb. Apart from the example shown of temporally constant currents, temporal relations as well as differences between the two currents of the current source IQ and the current sink IS can be set.

The temporal course of the voltage at the loop filter SF is shown in FIG. 3 for the case where the PLL circuit arrangement 100 locks in from a specific value of the voltage at the loop filter SF or of the control voltage, while the axis designations correspond to those of FIG. 2. Moreover, in the embodiment shown, the current of the phase detector PD in the locked in state compensates the current from the current source IQ or from the current sink IS. In this way, no switching voltages occur during the lock-in process when the PLL circuit arrangement 100 has a particularly high sensitivity. Furthermore, a lock-in process is shown in the figure for each operating mode, where branch a corresponds to the first operating state, in which the voltage at the loop filter SF, starting from the lower threshold value W1, is successively increased and branch b represents the second operating state, in which the voltage at the loop filter SF, starting from the upper threshold value W2, falls until it reaches the lock-in point. The same lock-in voltages were selected for both branches for reasons of clarity. The voltage at the loop filter SF is increased by the constant current of the current source IQ, while a high-frequency modulation voltage, whose frequency is proportional to the frequency difference present at the input of the phase detector PD, is superimposed by the modulated current from the phase detector PD. As, in the example shown, the difference between the frequency FO of the oscillator and the desired frequency FR at the input of the phase detector PD is still very large at the start of the search, it supplies a high-frequency modulation current whose amplitude is strongly damped by a set limiting frequency of the loop filter SF. The less the difference between the frequencies available at the input of the phase detector PD, the less the modulation frequency also becomes and thus the damping by the low pass characteristic of the loop filter SF. If the difference between the desired frequency FR and the oscillator frequency FO is small, the phase detector PD reduces the frequency of the modulation voltage and at the same time substantially increases the amplitude of the modulation voltage, while the current from the phase detector PD compensates the constant current of the current source IQ or current sink IS at the lock-in point of the PLL circuit. In the case of the phase-locked coupling, the voltage at the loop filter SF is thus held constant and the PLL circuit remains locked in.

What is claimed is:

1. Method for tuning a PLL circuit in which
a control voltage (VC), which is generated from a phase detector (PD) by means of a loop filter (SF), determines the output frequency (FO) of an oscillator (VCO), and
the output frequency (FO) in the phase detector (PD) is compared with a desired frequency (FR),
wherein
the control voltage (VC) is increased in a first operating mode until the output frequency (FO) matches the desired frequency (FR) or, provided the control voltage (VC) reaches a first threshold value,
the control voltage (VC) is decreased in a second operating mode until the output frequency (FO) matches the desired frequency (FR) or, provided the control voltage (VC) reaches a second threshold value, is switched into the first operating mode.

2. Method according to claim 1, wherein the change in the control voltage (VC) in the first operating mode is performed by means of a current source (IQ) and in the second operating mode by means of a current sink (IS), and their currents overlay with the current from the phase detector (PD).

3. Method according to claim 2, wherein the control voltage (VC) is held constant when the output frequency (FO) matches the desired frequency (FR), while the current of the phase detector (PD) compensates the current of the current source (IQ) or the current of the current sink (IS).

4. Method according to claim 3, wherein the control voltage (VC) is modulated provided the output frequency (FO) does not match the desired frequency (FR), while the phase detector (PD) supplies a temporally variable current to the loop filter (SF) the frequency of which is proportional to the size of the difference between the output frequency (FO) and the desired frequency (FR).

5. Method according to claim 4, wherein the maximum amplitude of the current of the phase detector (PD) is greater than the amplitude of the current from the current source (IQ)) or the current sink (IS).

6. Method according to claim 5, wherein the maximum amplitude of the current of the phase detector (PD) falls as the difference between the desired frequency (FR) and output frequency (FO) increases.

7. Method according to claim 6, wherein the modulation amplitude of the control voltage (VC) is damped by a low pass characteristic of the loop filter (SF).

8. Method according to claim 6 or claim 1, wherein the phase detector (PD) generates a control signal (LD) to indicate that the output frequency (FO) matches the desired frequency (FR).

9. PLL circuit arrangement for implementing the method according to the invention according to one or more of the previous claims with
a phase detector (PD) which is linked to a loop filter (SF), and
a voltage-controlled oscillator (VCO) which is wired to the loop filter (SF),
wherein
the circuit arrangement has at least one control unit (ST) which is linked to the loop filter (SF) and the phase detector (PD) in order to monitor the control voltage (VC) of the oscillator (VCO), and
has a current source (IQ) and a current sink (IS) which are linked to the loop filter (SF) by means of a switching element (E).

10. PLL circuit arrangement according to claim 11, wherein the control unit (ST) for comparing the control voltage with the two threshold values has at least one comparator and has at least one memory unit for storing the operating state.
